(19) United States
(12) Patent Application Publication
(10) Pub. No.: US 2005/0153476 A1
(43) Pub. Date: Jul. 14, 2005

(54) Flexible display and method of manufacturing the same

(75) Inventors: Kyung-bae Park, Seoul (KR); Takashi Noguchi, Gyeonggi-do (KR); Do-young Kim, Gyeonggi-do (KR); Jang-yeon Kwon, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 11/033,539

(22) Filed: Jan. 12, 2005

(30) Foreign Application Priority Data
Jan. 12, 2004 (KR) 10-2004-0001962

(51) Int. Cl. H01L 21/00; H01L 21/8242

(52) U.S. Cl. 438/98; 438/79

(57) ABSTRACT

Provided is a flexible display including a plastic substrate and a protective layer formed on the plastic substrate. Accordingly, the plastic substrate is protected from a thermal damage due to a thermal treatment, and sufficient thermal treatment for forming a polysilicon layer can be performed. Also, a polysilicon layer having a good surface and excellent prosperities can be formed due to reflection or absorption of a laser light by the protective layer. Consequently, the performance and durability of the flexible display are greatly improved.

Priority is claimed to Korean Patent Application No. 10-2004-0001962, filed on Jan. 12, 2004, in the Korean Intellectual Property Office, the disclosure of which is incorporated herein in its entirety by reference.

### BACKGROUND OF THE INVENTION

1. Field of the Invention

The present invention relates to a flexible display and a method of manufacturing a flexible display, and to a plastic substrate structure usable in the manufacture a flexible display, and a method of manufacturing a plastic display using the substrate structure.

2. Description of the Related Art

Examples of flexible displays include organic light-emitting diodes (OLED), thin film transistor liquid crystal displays (TFT LCD), and the like. In flexible displays, a substrate structure generally uses a plastic substrate. A unit element of a conventional flexible display will now be described with reference to FIG. 1A. FIG. LA is a cross-section of a unit element of a conventional flexible display.

Referring to FIG. 1A, an oxide layer 12, serving as a buffer layer, is formed on a plastic substrate 11. A polysilicon layer 13 is formed on the oxide layer 12. A source 14a and a drain 14b are formed on both side surfaces of the polysilicon layer 13. Typically, a portion of the polysilicon layer 13 between the source 14a and the drain 14b is referred to as a channel area. A gate structure composed of a gate oxide layer 15 and a gate electrode layer 16 is formed on the channel area. for example, the gate electrode layer 16 is formed of aluminum. However, the gate structure may have other shapes. The source 14a and the drain 14b are generally doped to have a polarity opposite to a polarity of the polysilicon layer 13. for example, if the polysilicon layer 13 is doped with an n-type dopant, the source 14a and the drain 14b are doped with a p-type dopant.

A process of forming the unit element of the conventional flexible display will now be described. First, the oxide layer 12 is formed by coating an upper surface of the plastic substrate 11 with an oxide. Then, the polysilicon layer 13 is formed by coating an upper surface of the plastic substrate 11 with amorphous silicon and thermally treating the amorphous silicon. Both sides of the polysilicon layer 13 are partially etched out.

Thereafter, the gate oxide layer 15 and the gate electrode layer 16 are formed on the polysilicon layer 13, and both lateral portions of each of the gate oxide layer 15 and the gate electrode layer 16 are etched out to thereby form the gate structure. Next, portions of the polysilicon layer 13 at both sides of the gate structure are doped with dopants and undergo thermal treatment, thereby forming the source 14a and the drain 14b. Then, a process, such as, formation of electrodes on the source 14a and the drain 14b, is performed, thus completing the formation of the unit element of the convention flexible display.

The oxide layer 12, serving as a buffer layer in the conventional flexible display, plays the following roles. First, the oxide layer 12 increases flatness of each layer, such as, the polysilicon layer 13, to be formed on the plastic substrate 11.

Second, the oxide layer 12 blocks external material generated from the plastic substrate 11 from being mixed with amorphous silicon that is under thermal treatment to form the polysilicon layer 13.

Third, the oxide layer 12 protects the plastic substrate 11 from laser energy used for thermal treatment.

Fourth, the oxide layer 12 protects the plastic substrate 11 from adverse effects of a chemical fabrication process and external material, such as oxygen or moisture.

As described above, the oxide layer 12, serving as the buffer layer, must be formed on the plastic substrate 11 as part of the process of fabrication of a flexible display. The aforementioned roles of the oxide layer 12 are very important in the conventional manufacture method of a flexible display.

As described above, the process of forming the unit element of the conventional flexible display includes several thermal treatment processes, which are used to form the polysilicon layer 13 and to form the source 14a and the drain 14b. Since the plastic substrate 11 has a melting point lower than a melting point of a silicon substrate or a glass substrate, the plastic substrate 11 has a thermal extension coefficient, which indicates a degree of deformation by heat, significantly greater than a thermal expansion coefficient of the silicon substrate or the glass substrate. Hence, particularly, misalignment occurs upon patterning. The most serious problem is that when laser is used to form the polysilicon layer 13 by coating the upper surface of the oxide layer 12 with amorphous silicon and crystallizing the amorphous silicon, the plastic substrate 11 is thermally damaged by the laser. On the other hand, when the polysilicon layer 13 is formed by executing thermal treatment on amorphous silicon instead of crystallizing the same, crystal growth is not properly achieved.

The thermal damage to the plastic substrate 11 can be recognized from the picture of FIG. 1B. Since the plastic substrate 11 is an organic polymer, it has a high absorbance in an ultraviolet range, particularly, in a wavelength range of 308 nm, such that it burns. FIG. 1C is a scanning electron microscope (SEM) picture of the upper surface of the oxide layer 12 that has underwent thermal treatment using laser to form the polysilicon layer 13. Referring to FIG. 1C, voids are generated, and the upper surface of the polysilicon layer 13 is rough, that is, has a very low flatness. This leads to a conclusion that the use of the oxide layer 12 is not enough to prevent the thermal damage to the plastic substrate 11.

### SUMMARY OF THE INVENTION

The present invention provides a substrate embodiments of which are capable of minimizing a damage to a plastic substrate due to thermal treatment during a manufacture of a flexible display, and a method of manufacturing the substrate.

According to an aspect of the present invention, there is provided a flexible display using a plastic substrate. The flexible display includes the plastic substrate and a protective layer formed on the plastic substrate.

Absorbance of light in a wavelength range of 200 to 400 nm by the protective layer may be less than 0.2.

The protective layer may include Al, AlNd, Cr, Ag, Co, Fe, or Pt.

The protective layer may be formed of Si, Ge, or GaAs.

A unit element of the flexible display can be an OLED, a TFT, a MOS transistor, or a diode.

The flexible display may further include an oxide layer formed on an upper surface of the protective layer, a polysilicon layer formed on an upper surface of the oxide layer, a source and a drain formed on both sides of the polysilicon layer and doped with a polarity opposite to a polarity of the polysilicon layer, and a gate structure formed on an upper surface of a portion of the polysilicon layer between the source and the drain.

According to another aspect of the present invention, there is provided a method of manufacturing a flexible display, the method including forming a protective layer on a plastic substrate.

The protective layer may be deposited by sputtering or evaporation.

The method further includes forming an oxide layer on an upper surface of the protective layer, forming a polysilicon layer by coating an upper surface of the oxide layer with amorphous silicon and thermally treating the amorphous silicon, and forming a gate structure on the polysilicon layer and forming a source and a drain by doping both edges of an upper surface of the polysilicon layer with a dopant.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-section of a unit element of a conventional flexible display;

FIG. 1B is a picture of a plastic substrate for use in the conventional flexible display of FIG. 1A that has underwent low-temperature heat treatment using laser;

FIG. 1C is a scanning electron microscope (SEM) picture of an upper surface of an oxide layer that underwent thermal treatment to form a polysilicon layer on the oxide layer;

FIG. 2 illustrates a substrate structure for use in a flexible display, according to an embodiment of the present invention;

FIGS. 3A through 3H are cross-sectional views illustrating a method of fabricating a unit element of a flexible display, according to an embodiment of the present invention;

FIG. 4A is a graph showing an absorbance of a substrate structure for use in a flexible display according to an embodiment of the present invention and absorbances of conventional substrates versus a laser with a wavelength range of 200 nm to 400 nm;

FIG. 4B shows pictures of surfaces of substrate structures for use in a conventional flexible display and a flexible display according to an embodiment of the present invention on which laser light has been projected;

FIG. 5A is an SEM picture of a surface of a polysilicon layer that underwent thermal treatment using a laser upon fabrication of a conventional flexible display; and

FIG. 5B is an SEM picture of a surface of a polysilicon layer that underwent thermal treatment using a laser upon fabrication of a flexible display according to an embodiment of the present invention.

### DETAILED DESCRIPTION OF THE INVENTION

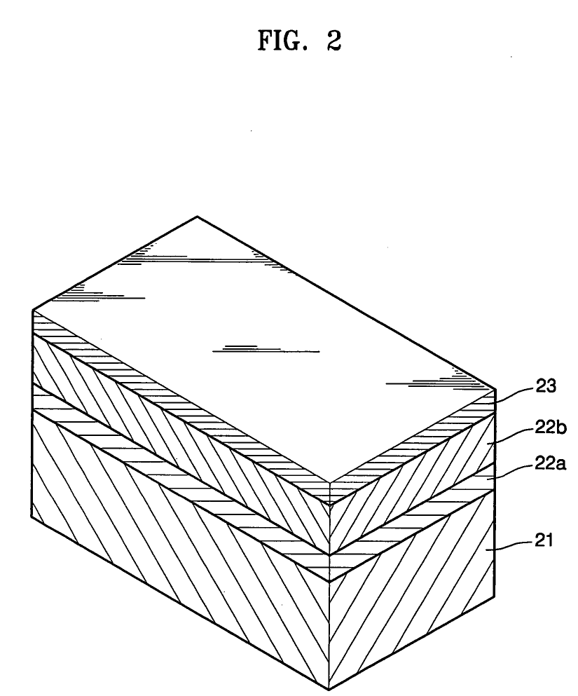

A flexible display and a method of fabricating a flexible display according to embodiments of the present invention will now be described in detail with reference to the drawings. The flexible display may use an OLED, a TFT, a metal oxide semiconductor (MOS) transistor, a diode, or the like, as a unit element. A plastic substrate is typically used as a substrate of the unit element of the flexible display. As an example, a TFT using a plastic substrate will now be described herein. FIG. 2 illustrates a substrate structure of a TFT in a flexible display according to an embodiment of the present invention.

Referring to FIG. 2, a protective layer 22a is formed on a plastic substrate 21, and an oxide layer 22b is formed on an upper surface of the protective layer 22a. A polysilicon layer 23 is formed on an upper surface of the oxide layer 22b. As described above, the substrate structure of the flexible display according to an embodiment of the present invention further includes the protective layer 22a, which is formed on the plastic substrate 21, as an addition to a substrate structure of a conventional flexible display. The protective layer 22a is formed of a metal or a semiconductor material. The metal reflects laser light having a predetermined wavelength range to be used in thermal treatment. The semiconductor material absorbs the laser light having the predetermined wavelength range. In other words, the flexible display according to an embodiment of the present invention includes the protective layer 22a, which is light-reflective or light-absorptive and does not transmit the laser light.

The reason why the light-reflective or light-absorptive protective layer 22a is formed on the plastic substrate 21 is that the protective layer 22a reflects or absorbs laser usually used upon thermal treatment to form the polysilicon layer 23 and/or a source and a drain, thereby preventing a thermal damage to the plastic substrate 21 and securing a stable growth of a device to be formed on the plastic substrate 21. Examples of a material of the protective layer 22a, for example, a metal, include Al, AlNd, Cr, Ag, Co, Fe, and Pt. As examples of light-absorptive semiconductor materials, Si, Ge, or GaAs, can be used as material of the protective layer 22a. When a metal is used to form the protective layer 22a, it is formed to a thickness of 10 Å or greater. When a semiconductor material is used to form the protective layer 22a, it is formed to a thickness of 100 Å or greater. These thicknesses may be adjusted if necessary.

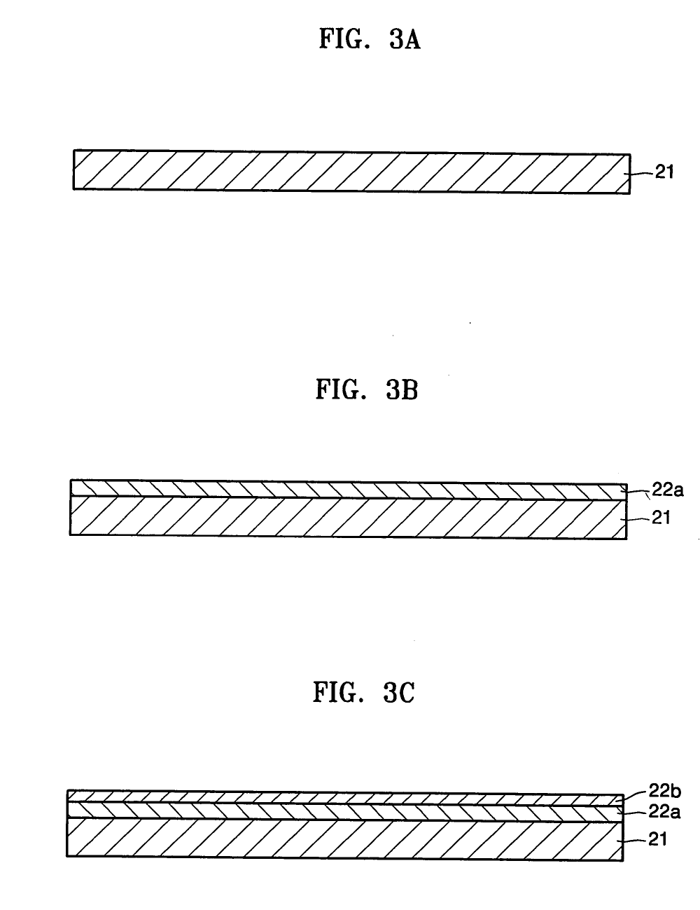

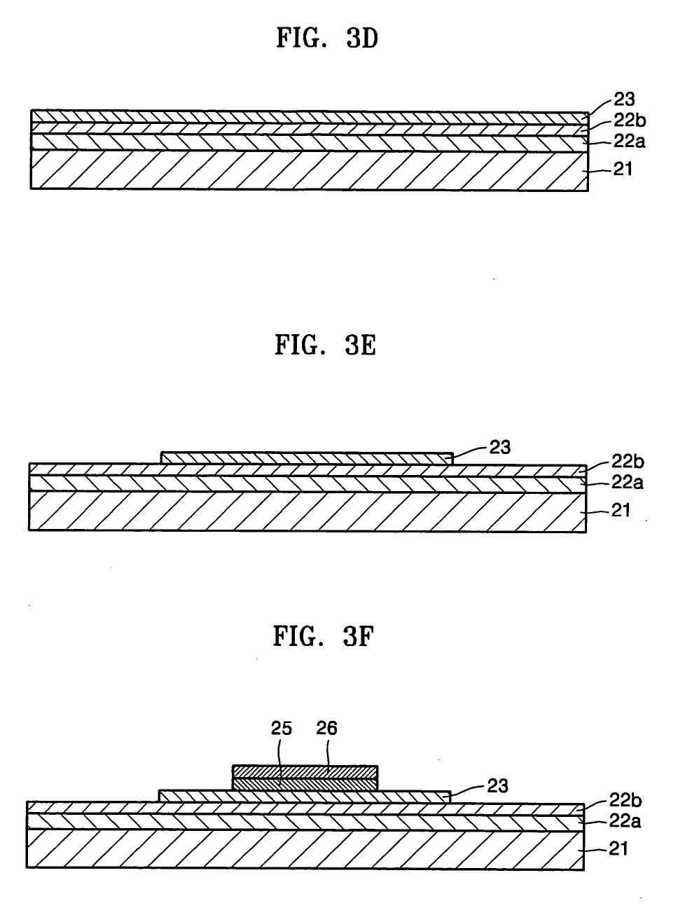

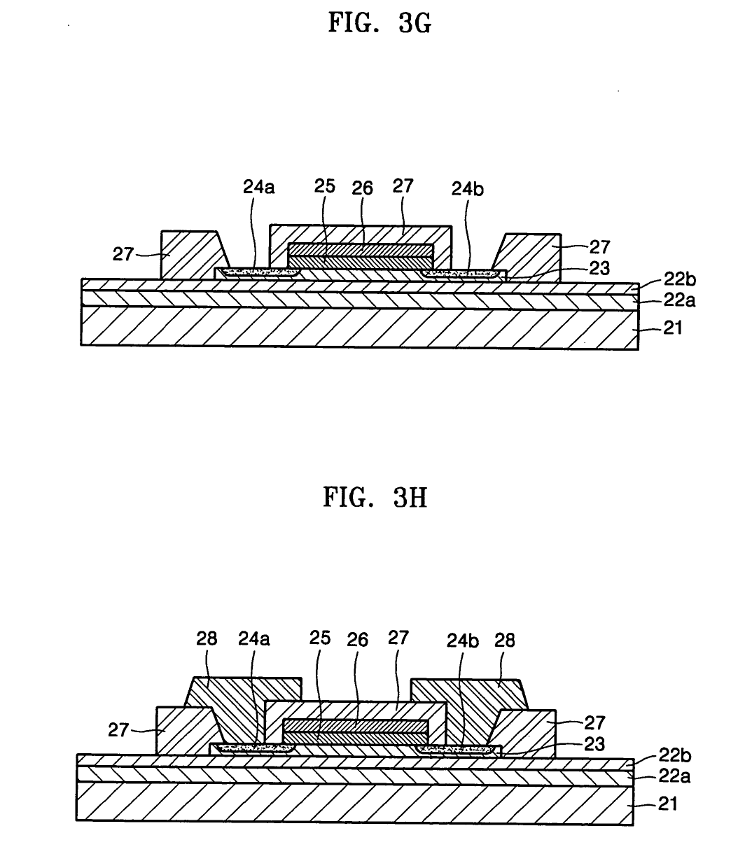

FIGS. 3A through 3H are cross-sectional views illustrating an exemplary method of fabricating a unit element of a flexible display according to an embodiment of the present invention. This unit element includes the substrate structure of FIG. 2.

First, as illustrated in FIG. 3A, a plastic substrate 21 is provided. As illustrated in FIG. 3B, the protective layer 22a is formed on the plastic substrate 21. The protective layer 22a may be formed of any material as long as it is highly reflective or absorptive to a wavelength range of a laser used for thermal treatment. If the protective layer 22a is formed of a metal, Al, AlNd, Cr, Ag, Co, Fe, or Pt may be used. If the protective layer 22a is formed of a semiconductor material, a light-absorptive semiconductor material, such as, Si, Ge, or GaAs, is preferably used. The protective layer 22a may be formed using a typical deposition method. As examples, the protective layer 22a is formed on the plastic substrate 11 using sputtering or evaporation.

Thereafter, as illustrated in FIG. 3C, the oxide layer 22b, serving as a buffer layer, is formed on the protective layer 22a. In the embodiment of the present invention, both the protective layer 22a and the oxide layer 22b substantially serve as buffer layers. The oxide layer 22b may be formed on the protective layer 22a by executing Inductive Coupled Plasma Chemical Vapor Deposition (ICP-CVD) for example on a material, such as, SiO₂.

Then, as illustrated in FIG. 3D, a polysilicon layer 23 is formed on the oxide layer 22b by coating an upper surface of the oxide layer 22b with amorphous silicon and thermally treating the amorphous silicon. Typically, the amorphous silicon coating is achieved using sputtering or plasma enhanced CVD (PE-CVD). To crystallize the amorphous silicon, a thermal treatment may be performed on the amorphous silicon by projecting a beam with a predetermined wavelength range from a XeCl eximer laser or the like onto the amorphous silicon. In the prior art, a surface of a plastic substrate is thermally damaged upon thermal treatment. However, in embodiments of the present invention, the projective layer 22a formed on the plastic substrate 21 can prevent thermal damage to the plastic substrate 21.

Next, as illustrated in FIG. 3E, both side portions of the polysilicon layer 23 are partially etched out. As illustrated in FIG. 3F, a gate structure is formed on a resultant structure of the polysilicon layer 23. The gate structure includes a gate oxide layer 25 and a gate electrode layer 26. The gate structure is formed when both side portions of the gate structure are removed to expose upper surfaces of both side portions of the polysilicon layer 23. Then, the exposed upper surfaces of the both side portions of the polysilicon layer 23 are doped with a dopant, so the dopant is implanted into the both side portions of the polysilicon layer 23, which are on both sides of the gate structure. The dopants are thermally treated with laser to form a source 24a and a drain 24b in the both side portions of the polysilicon layer 23 as illustrated in FIG. 3G.

In FIG. 3G, insulative layers 27 are formed by coating a surface of the gate structure (gate oxide layer 25 and gate electrode layer 26) and the both side portions of the polysilicon layer 23, which have the source 24a and the drain 24b, with an insulative material. In FIG. 3H, electrodes 28 are formed by coating upper surfaces of the source 24a and the drain 24b with a conductive material. Layer forming processes used in the fabrication of a conventional flexible display may be used to form the layers of the flexible display of FIGS. 3A through 3H.

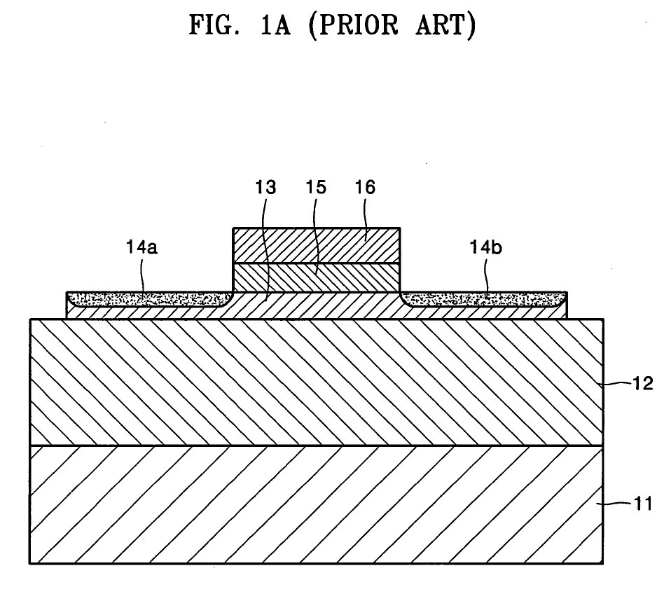

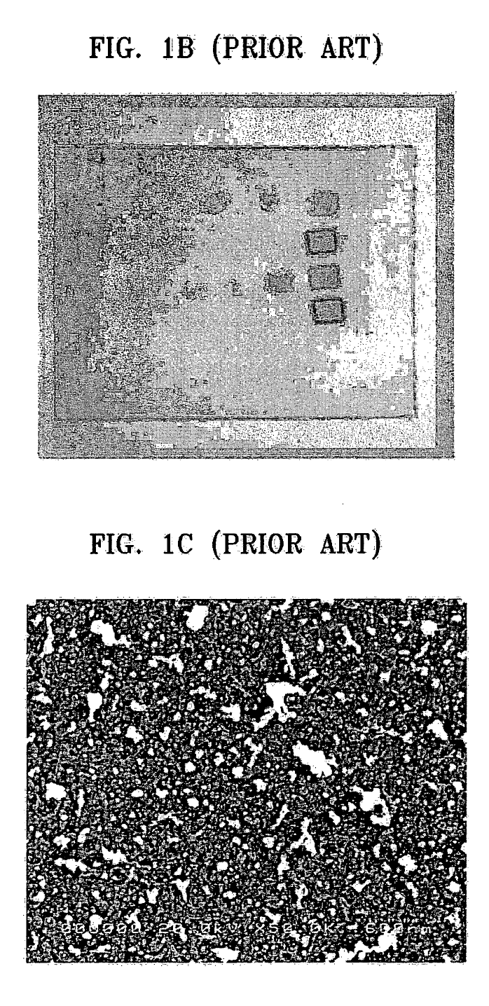

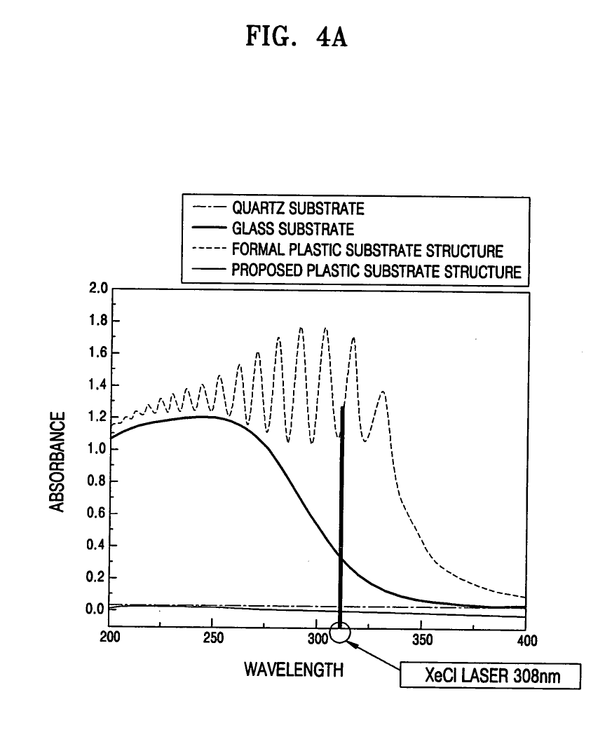

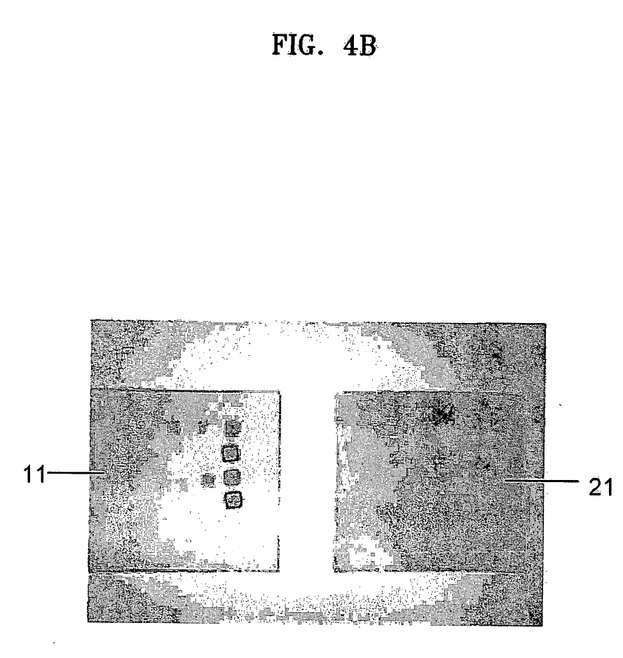

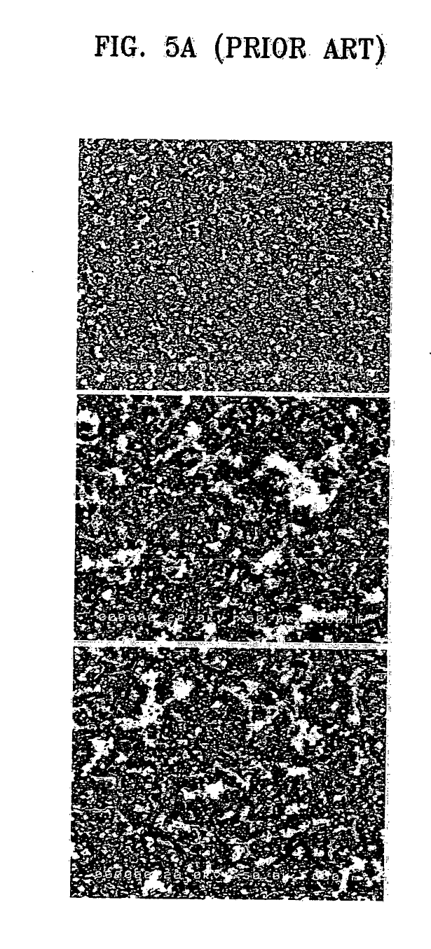

Absorbances of a substrate structure of a flexible display according to an embodiment of the present invention and conventional substrate structures with respect to a light wavelength range of 200 to 400 nm were measured and represented in FIG. 4A. FIG. 4A shows absorbances of a quartz substrate, a glass substrate, the plastic substrate structure of FIG. 1A, and a plastic substrate structure according to the above-described exemplary embodiment of the present invention when a UV ray having a wavelength of 200 to 400 nm was projected onto the substrate structures. Referring to FIG. 4A, the plastic substrate structure of FIG. 1A, conventionally used in a conventional flexible display, had the greatest absorbance with respect to the light wavelength. In other words, the substrate structure of FIG. 1A had an absorbance higher than the other substrate structures with respect to light used upon thermal treatment. Consequently, the plastic substrate structure of FIG. 1A has the greatest probability of having thermal damage among the other substrate structures.

The absorbance of the plastic substrate structure of FIG. 1A is followed by the absorbance of the glass substrate. The plastic substrate structure according to an embodiment of the present invention together with the quartz substrate had absorbencies lower than the absorbencies of the glass substrate and the plastic substrate structure of FIG. 1A. The absorbance of the plastic substrate according to an embodiment of the present invention is less than 0.2. Particularly, when a XeCl laser having a wavelength of 308 nm is used upon thermal treatment, the plastic substrate structure according to an embodiment of the present invention has the lowest absorbance among the other three substrates. It can be considered from this result that the plastic substrate structure according to the present invention has little thermal damage even when undergoing several thermal treatment processes in the manufacture of a flexible display.

FIG. 4B shows pictures of surfaces of plastic substrates 11 and 21 in the conventional substrate structure and the substrate structure according to an embodiment of the present invention, respectively, onto which a laser light having a 308 nm wavelength was projected. The plastic substrate 11 of the conventional substrate structure had thermal damage severe enough to be recognized, which was due to impingement of the laser light having the 308 nm wavelength. On the other hand, the plastic substrate 21 of the substrate structure according to an embodiment of the present invention had no marks of a thermal damage on a surface thereof. This difference between the conventional art and the present invention is generated while amorphous silicon is being thermally treated using a laser upon a manufacture of a flexible display. An outstanding effect of this embodiment of the present invention is the small amount of thermal damage to the plastic substrate.

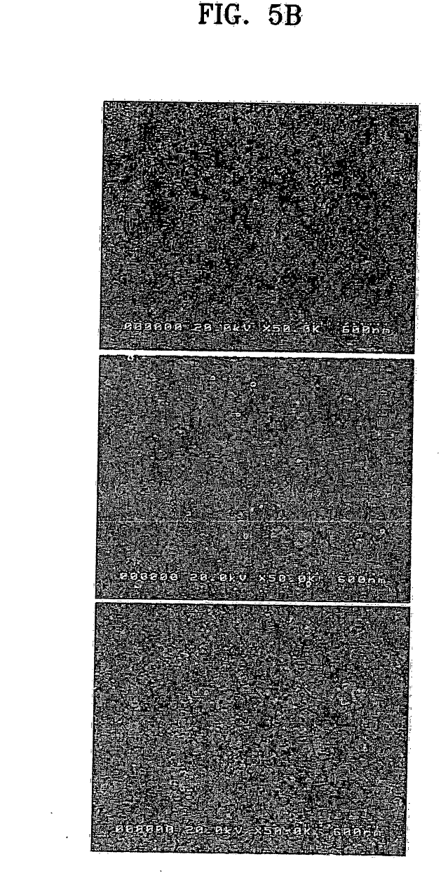

FIGS. 5A and 5B are SEM pictures of surfaces of polysilicon layers of a conventional plastic substrate structure and a plastic substrate structure according to an embodiment of the present invention that have underwent thermal treatments. FIG. 5A illustrates three pictures of a plastic substrate of the conventional plastic substrate structure that has a SiO₂ layer with a 200 nm thickness and an amorphous silicon layer with a 50 nm thickness formed thereon and is then thermally treated. FIG. 5B illustrates three pictures of a plastic substrate of the plastic substrate structure according to an embodiment of the present invention that has an Al metal layer with a 100 nm thickness, an SiO₂ layer with a 200 nm thickness, and an amorphous silicon layer with a 50 nm thickness formed thereon and is then thermally treated. In other words, a difference between FIGS. 5A and 5B is that the plastic substrate structure according to an embodiment of the present invention has the Al metal layer formed on the plastic substrate. The three pictures of the thermally treated plastic substrate in each of FIGS. 5A and 5B are obtained by projecting a laser having a 308 nm wavelength onto a surface of the amorphous silicon layer at an intensity of 100 mJ/cm₂ once at first, then five times, and then 20 times.

Referring to FIG. 5A, the roughness of a surface of the polysilicon layer increases with an increase in the frequency of laser radiations, a large number of voids are generated, and crystal defects gradually increase. In this case, when a display device is completely fabricated, light emission thereof may be degraded, and the life span thereof may be shortened. However, in FIG. 5B, even when the frequency of laser radiation increases, the surface roughness of the polysilicon layer is very low, and stable thermal treatment is performed.

Upon a manufacture of a flexible display according to an embodiment of the present invention, a plastic substrate structure is protected from a thermal damage due to a thermal treatment, and sufficient thermal treatment for forming a polysilicon layer can be performed. Also, a polysilicon layer having a good surface and excellent prosperities can be formed due to reflection or absorption of a laser light by a protective layer. Consequently, the performance and durability of the flexible display are greatly improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A flexible display using a plastic substrate, the flexible display comprising:
the plastic substrate; and
a protective layer formed on the plastic substrate.

2. The flexible display of claim 1, wherein absorbance of light in a wavelength range of 200 to 400 nm by the protective layer is less than 0.2.

3. The flexible display of claim 1, wherein the protective layer includes one of Al, AlNd, Cr, Ag, Co, Fe, and Pt.

4. The flexible display of claim 1, wherein the protective layer is formed of a semiconductor material.

5. The flexible display of claim 4, wherein the semiconductor material is one of Si, Ge, and GaAs.

6. The flexible display of claim 1, wherein a unit element of the flexible display is one of an organic light-emitting diode (OLED), a thin film transistor (TFT), a metal oxide semiconductor (MOS) transistor, and a diode.

7. The flexible display of claim 1, further comprising:
an oxide layer formed on an upper surface of the protective layer; and
a polysilicon layer formed on an upper surface of the oxide layer.

8. The flexible display of claim 1, further comprising:
a source and a drain formed on both sides of the polysilicon layer and doped to have a polarity opposite to a polarity of the polysilicon layer; and
a gate structure formed on an upper surface of a portion of the polysilicon layer between the source and the drain.

9. A method of manufacturing a flexible display, the method comprising forming a protective layer on a plastic substrate.

10. The method of claim 9, wherein the protective layer is formed by coating the plastic substrate with a metal whose absorbance of light in a wavelength range of 200 to 400 nm is less than 0.2.

11. The method of claim 9, wherein the protective layer includes one of Al, AlNd, Cr, Ag, Co, Fe, and Pt.

12. The method of claim 9, wherein the protective layer is formed of a semiconductor material of Si, Ge, and GaAs.

13. The method of claim 9, wherein the protective layer is deposited by sputtering or evaporation.

14. The method of claim 9, further comprising:
forming an oxide layer on an upper surface of the protective layer;
forming a polysilicon layer by coating an upper surface of the oxide layer with amorphous silicon and thermally treating the amorphous silicon; and
forming a gate structure on the polysilicon layer and forming a source and a drain by doping both edges of an upper surface of the polysilicon layer with a dopant.
